(19) United States
(12) Patent Application Publication
(10) Pub. No.: US 2024/0322513 A1
(43) Pub. Date: Sep. 26, 2024

(54) NARROW PULSE WIDTH LASER, METHOD FOR EMITTING NARROW PULSE WIDTH LASER, DEVICE, AND STORAGE MEDIUM

(71) Applicant: WUHAN RAYCUS FIBER LASER TECHNOLOGIES CO., LTD., Wuhan (CN)

(72) Inventors: Ouyang REN, Wuhan (CN); Feng CHANG, Wuhan (CN); Weiwen SHUAI, Wuhan (CN); Peng XU, Wuhan (CN); Dapeng YAN, Wuhan (CN)

(73) Assignee: WUHAN RAYCUS FIBER LASER TECHNOLOGIES CO., LTD., Wuhan (CN)

(21) Appl. No.: 18/735,718

(22) Filed: Jun. 6, 2024

Related U.S. Application Data
(63) Continuation of application No. PCT/CN2023/130295, filed on Nov. 7, 2023.

(30) Foreign Application Priority Data
Nov. 14, 2022 (CN) 202211417443.1

(51) Int. Cl. H01S 3/00; H01S 3/0941; H01S 5/042; H01S 5/062

(52) U.S. Cl. CPC H01S 3/0057; H01S 3/0941; H01S 5/0428; H01S 5/06216

(57) ABSTRACT

Disclosed are a narrow pulse width laser, a method for emitting narrow pulse width laser, a device, and a storage medium. The narrow pulse width laser includes: a pulse signal controller and a pulse laser emitter. An output end of the pulse signal controller is connected to an input end of the pulse laser emitter. The pulse signal controller is configured to obtain a first pulse signal and a second pulse signal, the first pulse signal is identical to the second pulse signal, the first pulse signal is controlled to delay for obtaining a delay signal, there is a target phase difference between the delay signal and the second pulse signal, the delay signal is superimposed on the second pulse signal to obtain a target pulse signal.

### CROSS-REFERENCE TO RELATED APPLICATIONS

The present application is a continuation application of International Application No. PCT/CN2023/130295, filed on Nov. 7, 2023, which claims priority to Chinese Patent Application No. 202211417443.1, filed on Nov. 14, 2022. The disclosures of the above-mentioned applications are incorporated herein by reference in their entireties.

### TECHNICAL FIELD

The present application relates to the field of laser technology, and in particular to a narrow pulse width laser, a method for emitting narrow pulse width laser, a device, and a storage medium.

### BACKGROUND

Among many laser technologies, pulse lasers, especially ultrashort pulse lasers, are widely used in the field of precision machining. Ultrashort pulse lasers refer to lasers whose single pulse width reaches or is less than picoseconds. Since the laser pulse time width is extremely short, the set laser power needs to be released at a certain frequency (i.e., a certain number of pulses). The laser power of a single pulse is fixed. The energy of a single pulse is released in a very short time, resulting in extremely high instantaneous power (megawatts and above). High peak power can instantly change the properties of materials. The processing effect with very low average power and little thermal effect on the material processing area is laser cold processing. Therefore, controlling the laser to output narrow pulse width lasers that meet application requirements has become a key research direction for pulse lasers.

At present, the method of outputting narrow pulse width laser is to use a narrow pulse width control signal to drive the corresponding seed source. The narrow pulse width control signal is obtained by clipping the amplitude of the signal through a clipper. However, when the narrow pulse width control signal obtained by clipping is used to drive the seed light emitted by the seed source, the signal amplitude of the control signal becomes smaller, which may reduce the power of the seed light output corresponding to the seed source.

In view of the problems in the related art such as large laser power loss output by narrow pulse width laser, no effective solution has been provided.

### SUMMARY

The embodiments of the present application provide a narrow pulse width laser, a method for emitting narrow pulse width laser, a device, and a storage medium to at least solve the problem of large laser power loss output by narrow pulse width laser in the related art.

According to an embodiment of the present application, a narrow pulse width laser is provided, including: a pulse signal controller and a pulse laser emitter, the output end of the pulse signal controller is connected to the input end of the pulse laser emitter.

The pulse signal controller is configured to obtain a first pulse signal and a second pulse signal, the first pulse signal is identical to the second pulse signal, the first pulse signal is controlled to delay for obtaining a delay signal, there is a target phase difference between the delay signal and the second pulse signal, the delay signal is superimposed on the second pulse signal to obtain a target pulse signal, the pulse width of the target pulse signal is less than the pulse width of the second pulse signal.

The pulse laser emitter is configured to emit a target pulse laser using the target pulse signal.

In an embodiment, the pulse signal controller includes: a signal generating unit, a delay chip and an AND gate chip. An input end of the delay chip is connected to an output end of the signal generating unit, an output end of the delay chip is connected to an input end of the AND gate chip, another output end of the signal generating unit is connected to another input end of the AND gate chip, and an output end of the AND gate chip is connected to the input end of the pulse laser emitter.

The signal generating unit is configured to generate the first pulse signal and the second pulse signal.

The delay chip is configured to obtain delay configuration parameters, the delay configuration parameters are configured to configure the target phase difference by controlling the delay of the first pulse signal, the first pulse signal is delayed according to the delay configuration parameters to obtain the delay signal.

The AND gate chip is configured to perform an AND operation on the delay signal and the second pulse signal to obtain the target pulse signal.

In an embodiment, the delay chip further includes: a delay type port, a delay value port and a delay direction port.

The delay type port is configured to obtain the delay type. The delay value port is configured to obtain the delay value. The delay direction port is configured to obtain the delay direction.

The delay configuration parameters include: the delay type, the delay value, and the delay direction.

In an embodiment, the narrow pulse width laser further includes a parameter controller, the parameter controller is connected to the signal generating unit, the delay type port, the delay value port, and the delay direction port.

The parameter controller is configured to determine the target phase difference according to the first pulse signal, determine the delay configuration parameter according to the target phase difference, and send the delay configuration parameters to the delay chip.

According to another embodiment of the present application, a method for emitting narrow pulse width laser is provided. The method includes:
obtaining a first pulse signal and a second pulse signal, the first pulse signal is identical to the second pulse signal;
controlling the first pulse signal to delay and obtaining a delay signal, there is a target phase difference between the delay signal and the second pulse signal;
superimposing the delay signal on the second pulse signal to obtain a target pulse signal, the pulse width of the target pulse signal is less than the pulse width of the second pulse signal; and
emitting the target pulse laser using the target pulse signal.

In an embodiment, the controlling the first pulse signal to delay and obtaining the delay signal includes:
obtaining delay configuration parameters, the delay configuration parameters are configured to configure the target phase difference by controlling the delay of the first pulse signal; and
delaying the first pulse signal according to the delay configuration parameters to obtain the delay signal.

In an embodiment, before the delaying the first pulse signal according to the delay configuration parameters, the method further includes:
detecting a signal parameter of the first pulse signal;
determining the target phase difference according to the signal parameter; and
determining the delay configuration parameters according to the target phase difference.

According to another embodiment of the present application, a narrow pulse laser emission device is further provided. The device includes: an acquisition module, a control module, a superposition module, and an emission module.

The acquisition module is configured to acquire a first pulse signal and a second pulse signal, the first pulse signal is identical to the second pulse signal.

The control module is configured to control the delay of the first pulse signal to obtain a delay signal, there is a target phase difference between the delay signal and the second pulse signal.

The superposition module is configured to superimpose the delay signal and the second pulse signal to obtain a target pulse signal, the pulse width of the target pulse signal is less than the pulse width of the second pulse signal.

The emission module is configured to emit the target pulse laser using the target pulse signal.

According to another aspect of the embodiment of the present application, a computer-readable storage medium is further provided. The computer-readable storage medium stores a computer program, the computer program is configured to implement the above-mentioned method for emitting narrow pulse width laser when executed.

According to another aspect of the embodiment of the present application, an electronic device is further provided, including a memory, a processor, and a computer program stored in the memory and executable on the processor, the processor executes the method for emitting narrow pulse width laser through the computer program.

In an embodiment of the present application, a narrow pulse width laser includes: a pulse signal controller, and a pulse laser emitter. The output end of the pulse signal controller is connected to the input end of the pulse laser emitter. The pulse signal controller is configured to obtain a first pulse signal and a second pulse signal. The first pulse signal is identical to the second pulse signal. The first pulse signal is controlled to delay for obtaining a delay signal. There is a target phase difference between the delay signal and the second pulse signal. The delay signal is superimposed on the second pulse signal to obtain a target pulse signal. The pulse laser emitter is configured to emit a target pulse laser using a target pulse signal. That is, the narrow pulse width laser includes a pulse signal controller and a pulse laser emitter. After the pulse signal controller obtains the first pulse signal and the second pulse signal, the first pulse signal is first controlled to delay for obtaining a delay signal so that there is a target phase difference between the delay signal and the second pulse signal. Then the delay signal is superimposed on the second pulse signal to obtain a target pulse signal. At this time, the pulse width of the obtained target pulse signal is less than the pulse width of the second pulse signal, and the corresponding signal amplitude is not reduced. Since the signal amplitude of the target pulse signal is unchanged compared to the first pulse signal and the second pulse signal, the target pulse laser emitted by the subsequent pulse laser emitter using the target pulse signal retains the pulse width of the target pulse signal, and the corresponding laser power will not be lost. The above technical solution is adopted to solve the problem of large laser power loss output by narrow pulse width laser in the related art, and achieves the technical effect of reducing the laser power loss output by narrow pulse width laser.

### BRIEF DESCRIPTION OF THE DRAWINGS

The accompanying drawings herein are incorporated into and constitute a part of the specification, and illustrate embodiments consistent with the present application, and together with the specification, are used to explain the principles of the present application.

In order to more clearly illustrate the technical solutions in the embodiments of the present application or in the related art, drawings used in the embodiments or in the related art will be briefly described below. Obviously, the drawings in the following description are only some embodiments of the present application. It will be apparent to those skilled in the art that other figures can be obtained according to the structures shown in the drawings without creative work.

FIG. 1 is a schematic diagram of a narrow pulse width laser according to an embodiment of the present application.

FIG. 2 is a structural diagram of the narrow pulse width laser according to an embodiment of the present application.

FIG. 3 is a schematic diagram of a pulse signal controller according to an embodiment of the present application.

FIG. 4 is a schematic diagram of an AND gate chip principle according to an embodiment of the present application.

FIG. 5 is a schematic diagram of a delay chip according to an embodiment of the present application.

FIG. 6 is a schematic diagram of another parameter controller according to an embodiment of the present application.

FIG. 7 is a schematic diagram of hardware environment of a method for emitting narrow pulse width laser according to an embodiment of the present application.

FIG. 8 is a flowchart of the method for emitting narrow pulse width laser according to an embodiment of the present application.

FIG. 9 is a structural block diagram of a narrow pulse laser emission device according to an embodiment of the present application.

### DETAILED DESCRIPTION OF THE EMBODIMENTS

In order to enable those skilled in the art to better understand the present application, the following will be combined with the drawings in the embodiments of the present application to clearly and completely describe the technical solutions in the embodiments of the present application. Obviously, the described embodiments are only embodiments of a part of the present application, not all embodiments. Based on the embodiments in the present application, all other embodiments obtained by ordinary skilled in the art without creative work should fall within the scope of protection of this application.

It should be noted that the terms “first”, “second”, etc. in the specification and claims of the present application and the above-mentioned drawings are used to distinguish similar objects. They are not necessarily used to describe a specific order or sequence. It should be understood that the data used in this way can be interchangeable where appropriate. So that the embodiments of the present application described here can be implemented in an order other than those illustrated or described here. In addition, the terms “including” and “comprising” and any of their variations are intended to cover non-exclusive inclusions. For example, a process, method, system, product or device that includes a series of steps or units is not necessarily limited to those steps or units clearly listed. Instead, it may include other steps or units that are not clearly listed or inherent to these processes, methods, products or devices.

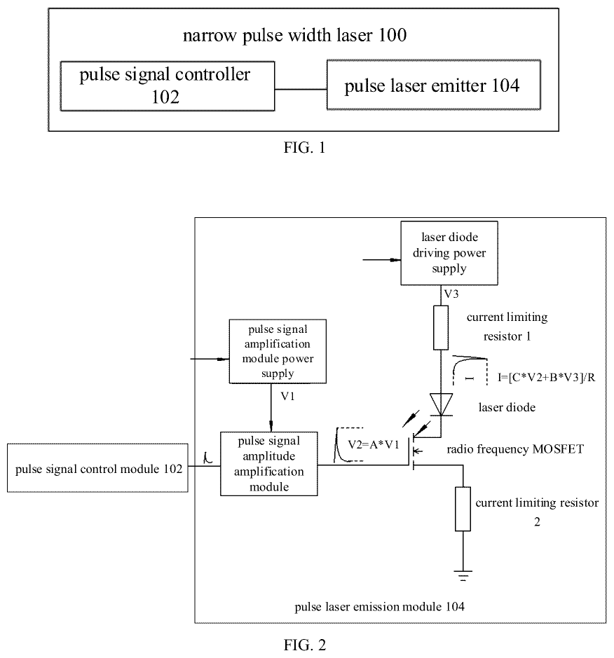

A narrow pulse width laser is provided in the embodiment of the present application. FIG. 1 is a schematic diagram of a narrow pulse width laser according to an embodiment of the present application. As shown in FIG. 1, the narrow pulse width laser 100 includes: a pulse signal controller 102 and a pulse laser emitter 104. Among them, the output end of the pulse signal controller 102 is connected to the input end of the pulse laser emitter 104.

The pulse signal controller 102 is configured to obtain a first pulse signal and a second pulse signal. The first pulse signal is identical to the second pulse signal. The delay of the first pulse signal is controlled to obtain a delay signal. There is a target phase difference between the delay signal and the second pulse signal. The delay signal is superimposed on the second pulse signal to obtain a target pulse signal. The pulse width of the target pulse signal is less than the pulse width of the second pulse signal.

The pulse laser emitter 104 is configured to emit a target pulse laser using the target pulse signal.

In an embodiment, the pulse signal controller controls the mutual delay time of the first pulse signal and the second pulse signal. Pulse signals of different widths are obtained at the AND gate. The repetition frequency of the input signal is the repetition frequency of the superimposed signal. The pulse signal output in this way is generated by phase superposition. Compared with the narrow pulse signal generated by clipping, its pulse width stability will be better. After the waveform amplitude and power change, the original pulse width information can be better maintained.

In an embodiment, the pulse laser emitter may include, but is not limited to, a pulse signal amplitude amplification module, a pulse signal amplification module power supply, a radio frequency metal-oxide-semiconductor field-effect transistor (MOSFET), a laser diode, a laser diode driving power supply and current limiting resistors (a current limiting resistor 1 and a current limiting resistor 2). FIG. 2 is a structural diagram of the narrow pulse width laser according to an embodiment of the present application. As shown in FIG. 2, the pulse signal controller outputs a target pulse signal, which is transmitted to the pulse signal amplitude amplification module. The voltage loaded on the pulse signal amplitude amplification module by the pulse signal amplification module power supply is controlled, and the amplification amplitude of the target pulse signal by the pulse signal amplitude amplification module is controlled, an amplified pulse signal is obtained. The amplitude of the amplified pulse signal is V2. The amplitude of the target pulse signal is V1. V2=A*V1. A is the amplitude amplification factor. The amplified pulse signal drives the radio frequency MOSFET, which is converted into a pulse current to drive the laser diode. The laser diode emits a pulse laser under the pulse current drive. The pulse current magnitude I is related to the input pulse amplitude and the output voltage V3 of the laser diode driving power supply:

$$\\ I = \frac{C * {V}_{2} + B * {V}_{3}}{R} .$$

C and B are constants. R is the total resistance of the circuit in which the laser diode is located. The output power of the laser diode is proportional to the current passing through it. Therefore, by adjusting the output voltage V1 of the pulse signal amplification module power supply and the voltage V3 of the laser diode driving power supply, the output power of the laser diode can be controlled.

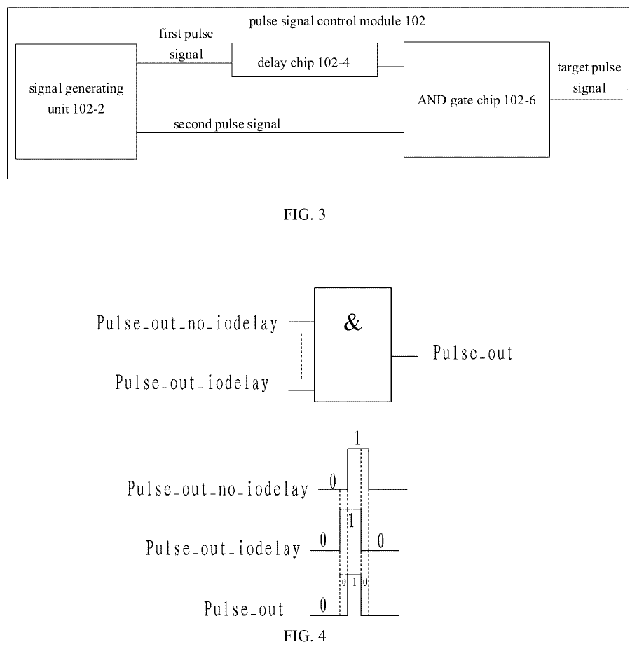

In an embodiment, FIG. 3 is a schematic diagram of a pulse signal controller according to an embodiment of the present application. As shown in FIG. 3, the pulse signal controller 102 includes: a signal generating unit 102-2. A delay chip 102-4 and an AND gate chip 102-6. The input end of the delay chip 102-4 is connected to an output end of the signal generating unit 102-2. The output end of the delay chip 102-4 is connected to an input end of the AND gate chip 102-6. Another output end of the signal generating unit 102-2 is connected to another input end of the AND gate chip 102-6. The output end of the AND gate chip 102-6 is connected to the input end of the pulse laser emitter 104.

The signal generating unit 102-2 is configured to generate the first pulse signal and the second pulse signal.

The delay chip 102-4 is configured to obtain delay configuration parameters. The delay configuration parameters are configured to configure the target phase difference by controlling the delay of the first pulse signal. The first pulse signal is delayed according to the delay configuration parameters to obtain the delay signal.

The AND gate chip 102-6 is configured to perform an AND operation on the delay signal and the second pulse signal to obtain the target pulse signal.

In an embodiment, the AND gate chip is configured to perform an AND operation on the input delay signal and the second pulse signal to obtain the target pulse signal. The AND gate chip can be, but is not limited to, an AND gate in a field programmable gate array (FPGA) chip. FIG. 4 is a schematic diagram of an AND gate chip principle according to an embodiment of the present application. As shown in FIG. 4, the delay signal (Pulse_out_iodelay) and the second pulse signal (Pulse_out_no_iodelay) enter the AND gate chip, and the target pulse signal (Pulse_out) is output. The Pulse_out_iodelay has a high level 1 and Pulse_out_no_iodelay has a low level 0. The AND gate chip is configured to superimpose the signals of Pulse_out_iodelay and Pulse_out_no_iodelay. That is, the pulse width corresponding to the part where the high level 1 overlaps is used as the pulse width of Pulse_out. The mutual delay time of Pulse_out_iodelay and Pulse_out_no_iodelay is controlled, and pulse signals of different widths are obtained at the AND gate. The repetition frequency of the input signal is the repetition frequency of the superimposed signals. The pulse signal output by this method is generated by phase superposition. Compared with the narrow pulse signal generated by clipping, its pulse width stability will be better, and the original pulse width information can be better maintained after the waveform amplitude and power change.

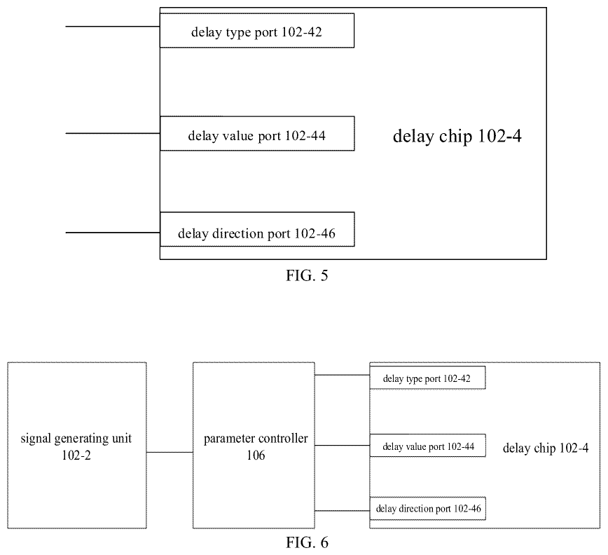

In an embodiment, FIG. 5 is a schematic diagram of a delay chip according to an embodiment of the present application. As shown in FIG. 5, the delay chip 102-4 further includes: a delay type port 102-42, a delay value port 102-44, and a delay direction port 102-46.

The delay type port 102-42 is configured to obtain the delay type. The delay value port 102-44 is configured to obtain the delay value. The delay direction port 102-46 is configured to obtain the delay direction.

The delay configuration parameters include: the delay type, the delay value and the delay direction.

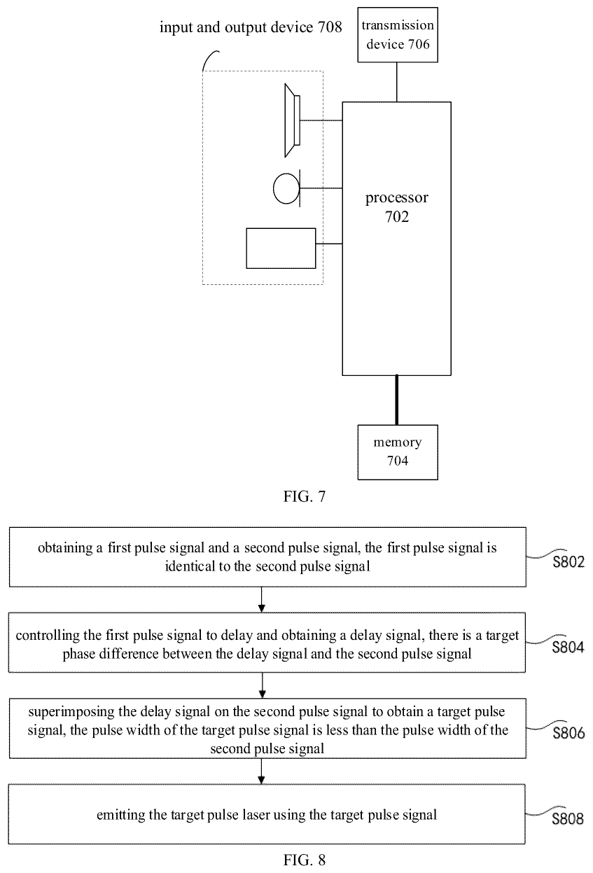

In an embodiment, as shown in FIG. 7, the delay configuration parameters may include sdtap (delay type), setn (delay direction), and value (specific delay value).

In an embodiment, FIG. 6 is a schematic diagram of another parameter controller according to an embodiment of the present application. As shown in FIG. 6, the narrow pulse width laser 100 further includes: a parameter controller 106. The parameter controller 106 is connected to the signal generating unit 102-2, the delay type port 102-42, the delay value port 102-44, and the delay direction port 102-46.

The parameter controller 106 is configured to determine the target phase difference according to the first pulse signal, determine the delay configuration parameter according to the target phase difference, and send the delay configuration parameter to the delay chip 102-4.

In an embodiment, the target phase difference is related to the initial pulse width of the first pulse signal. The delay configuration parameter is calculated according to the target phase difference. The delay chip is controlled by the delay configuration parameter to delay the first pulse signal, and output the delay signal. The delay signal is then superimposed on the second pulse signal, and the target pulse signal is output.

The method for emitting narrow pulse width laser provided in the embodiment of the present application can be executed in a computer terminal, a device terminal or a similar computing device. Take running on a computer terminal as an example. FIG. 7 is a schematic diagram of hardware environment of a method for emitting narrow pulse width laser according to an embodiment of the present application. As shown in FIG. 7, computer terminal may include one or more (only one is shown in FIG. 7) processors 702 (the processor 702 may include but is not limited to a processing device such as a microprocessor main control unit (MCU) or a programmable logic device FPGA) and a memory 704 for storing data. In an embodiment, the above-mentioned computer terminal may further include a transmission device 706 for communication functions and an input and output device 708. It can be understood by those skilled in the art that the structure shown in FIG. 7 is only for illustration, it does not limit the structure of the above-mentioned computer terminal. For example, the computer terminal may further include more or fewer components than those shown in FIG. 7, or have a different configuration with the same function as shown in FIG. 7 or more functions than those shown in FIG. 7.

The memory 704 can be configured to store computer programs. For example, software programs and modules of application software. For example, the computer program corresponding to the method for sending message push in the embodiment of the present application. The processor 702 executes various functional applications and data processing by running the computer program stored in the memory 704, that is, the above method is implemented. The memory 704 may include a high-speed random access memory (RAM). It may further include a non-volatile memory (NVM). Such as one or more magnetic storage devices, flash memory, or other non-volatile solid-state memory. In an embodiment, the memory 704 may further include a memory remotely arranged relative to the processor 702, these remote memories can be connected to the computer terminal via a network. Examples of the above-mentioned network include but are not limited to the Internet, corporate intranet, local area network (LAN), mobile communication network and combinations thereof.

The transmission device 706 is configured to receive or send data via a network. The specific example of the above network may include a wireless network provided by a communication provider of a computer terminal. In an embodiment, the transmission device 706 includes a network adapter (network interface controller (NIC)). It can be connected to other network devices through a base station so as to communicate with the Internet. In an embodiment, the transmission device 706 can be a radio frequency (RF) module. It is configured to communicate with the Internet wirelessly.

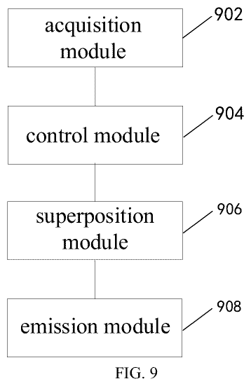

In an embodiment, a method for emitting a narrow pulse width laser is provided, which is applied to the above-mentioned computer terminal. FIG. 8 is a flowchart of the method for emitting narrow pulse width laser according to an embodiment of the present application. As shown in FIG. 8, the process includes the following steps.

Step S802: obtaining a first pulse signal and a second pulse signal, the first pulse signal is identical to the second pulse signal.

Step S804: controlling the first pulse signal to delay and obtaining a delay signal, there is a target phase difference between the delay signal and the second pulse signal.

Step S806: superimposing the delay signal on the second pulse signal to obtain a target pulse signal, the pulse width of the target pulse signal is less than the pulse width of the second pulse signal.

Step S808: emitting the target pulse laser using the target pulse signal.

Through the above steps, the first pulse signal and the second pulse signal are firstly obtained. Then the first pulse signal is controlled to delay for obtaining the delay signal. At this time, there is a target phase difference between the delay signal and the second pulse signal. Then the delay signal and the second pulse signal are superimposed to obtain the target pulse signal. Therefore, the pulse width of the target pulse signal is less than the pulse width of the second pulse signal. Since the signal amplitude of the target pulse signal has not changed, the target pulse laser is emitted by the target pulse signal. The target pulse laser retains the narrow pulse width characteristics, and reduces the laser power loss output by the narrow pulse width laser. The above technical solution is adopted to solve the problem of large laser power loss output by narrow pulse width laser in the related art, and achieves the technical effect of reducing the laser power loss output by narrow pulse width laser.

In the technical solution provided in the above step S802, the first pulse signal and the second pulse signal can be, but are not limited to, separated from the same source signal. The first pulse signal and the second pulse signal have completely the same parameters such as signal amplitude, signal pulse width, signal frequency, etc.

In the technical solution provided in the above step S804, the delay may refer to, but is not limited to, the propagation time of the delay signal. It may be, but is not limited to, implemented by a delay module. The delay module includes a preset delay configuration parameter. The delay configuration parameter indicates the degree of delay of the first pulse signal. Thereby, the target phase difference between the delay signal and the second pulse signal is achieved.

In an embodiment, the delay of the first pulse signal may be controlled by, but is not limited to, the following manners to obtain the delay signal: obtaining a delay configuration parameter. The delay configuration parameters are configured to configure the target phase difference by controlling the delay of the first pulse signal. The first pulse signal is delayed according to the delay configuration parameters to obtain the delay signal.

In an embodiment, before delaying the first pulse signal, it is necessary to obtain the delay configuration parameters in advance. The delay configuration parameter is then configured to indicate the manner of delaying the first pulse signal.

In an embodiment, before delaying the first pulse signal according to the delay configuration parameter, the following manners may also be included: detecting a signal parameter of the first pulse signal, determining the target phase difference according to the signal parameter, and determining the delay configuration parameter according to the target phase difference.

In an embodiment, the delay configuration parameters can be obtained by, but are not limited to, calculation. The delay configuration parameters are related to the signal parameters of the first pulse signal, such as signal frequency, signal pulse width, signal bandwidth, etc. First, the signal parameters of the first pulse signal can be detected. Then, the target phase difference is determined based on the signal parameters. Finally, the delay configuration parameters matching the target phase difference are determined.

In the technical solution provided in the above step S806, the superposition manner may be to retain the part where the delay signal overlaps with the high level of the second pulse signal, so as to control the pulse width of the target pulse signal after superposition to be less than the pulse width of the second pulse signal.

In the technical solution provided in the above step S808, since the target pulse signal is generated by phase superposition, compared with the narrow pulse signal generated by clipping, its pulse width stability will be better, and the original pulse width information can be better maintained after the waveform amplitude and power change.

Through the description of the above implementation manners. Those skilled in the art can clearly understand that the method according to the above embodiment can be implemented by means of software plus a necessary general hardware platform. Of course, it can also be implemented by hardware. But in many cases the former is a better implementation method. Based on this understanding. The technical solution of the present application can essentially or contribute to the prior art in the form of a software product. The computer software product is stored in a storage medium (such as read-only memory (ROM)/random access memory (RAM), disk, CD). It includes a number of instructions for a terminal device (which can be a mobile phone. Computer. Server. Or network equipment, etc.) to execute the methods of each embodiment of the present application.

FIG. 9 is a structural block diagram of a narrow pulse width laser emission device according to an embodiment of the present application. As shown in FIG. 9, the narrow pulse laser emission device includes: an acquisition module 902, a control module 904, a superposition module 906, and an emission module 908.

The acquisition module 902 is configured to acquire a first pulse signal and a second pulse signal, the first pulse signal is identical to the second pulse signal.

The control module 904 is configured to control the delay of the first pulse signal to obtain a delay signal, there is a target phase difference between the delay signal and the second pulse signal.

The superposition module 906 is configured to superimpose the delay signal and the second pulse signal to obtain a target pulse signal, the pulse width of the target pulse signal is less than the pulse width of the second pulse signal.

The emission module 908 is configured to emit the target pulse laser using the target pulse signal.

Through the above steps, the first pulse signal and the second pulse signal are firstly obtained. Then the first pulse signal is controlled to delay for obtaining the delay signal. At this time, there is a target phase difference between the delay signal and the second pulse signal. Then the delay signal and the second pulse signal are superimposed to obtain the target pulse signal. Therefore, the pulse width of the target pulse signal is less than the pulse width of the second pulse signal. Since the signal amplitude of the target pulse signal has not changed, the target pulse laser is emitted by the target pulse signal. The target pulse laser retains the narrow pulse width characteristics, and reduces the laser power loss output by the narrow pulse width laser. The above technical solution is adopted to solve the problem of large laser power loss output by narrow pulse width laser in the related art, and achieves the technical effect of reducing the laser power loss output by narrow pulse width laser.

In an embodiment, the control module includes: an acquisition unit, and a delay unit.

The acquisition unit is configured to obtain delay configuration parameters. The delay configuration parameters are configured to configure the target phase difference by controlling the delay of the first pulse signal.

The delay unit is configured to delay the first pulse signal according to the delay configuration parameters to obtain the delay signal.

In an embodiment, the device further includes: a detection module, a first determination module, and a second determination module.

The detection module is configured to detect the signal parameters of the first pulse signal before delaying the first pulse signal according to the delay configuration parameters.

The first determination module is configured to determine the target phase difference according to the signal parameter.

The second determination module is configured to determine the delay configuration parameters according to the target phase difference.

The embodiment of the present application further provides a storage medium. The storage medium includes a stored program. When the program is executed, any of the above methods is implemented.

In an embodiment, the storage medium may be configured to store program codes for executing the steps of the above-mentioned method for emitting a narrow pulse width laser.

Step S802: obtaining a first pulse signal and a second pulse signal, the first pulse signal is identical to the second pulse signal.

Step S804: controlling the first pulse signal to delay and obtaining a delay signal, there is a target phase difference between the delay signal and the second pulse signal.

Step S806: superimposing the delay signal on the second pulse signal to obtain a target pulse signal, the pulse width of the target pulse signal is less than the pulse width of the second pulse signal.

Step S808: emitting the target pulse laser using the target pulse signal.

The embodiment of the present application further provides an electronic device, including a memory and a processor. A computer program is stored on the memory, and the processor is configured to run the computer program to execute the steps in any one of the above method embodiments.

In an embodiment, the electronic device may further include a transmission device and an input/output device. The transmission device is connected to the processor, and the input/output device is connected to the processor.

In an embodiment, the processor may be configured to perform the steps of the above-mentioned method for emitting a narrow pulse width laser through a computer program.

Step S802: obtaining a first pulse signal and a second pulse signal, the first pulse signal is identical to the second pulse signal.

Step S804: controlling the first pulse signal to delay and obtaining a delay signal, there is a target phase difference between the delay signal and the second pulse signal.

Step S806: superimposing the delay signal on the second pulse signal to obtain a target pulse signal, the pulse width of the target pulse signal is less than the pulse width of the second pulse signal.

Step S808: emitting the target pulse laser using the target pulse signal.

In an embodiment, the storage medium may include but is not limited to: a USB flash drive, a ROM, a RAM, a mobile hard disk, a magnetic disk or an optical disk, and other media that can store program codes.

For specific examples in this embodiment, reference may be made to the examples described in the above embodiments and optional implementation modes, and this embodiment will not be described in detail here.

Obviously, those skilled in the art should understand that the above modules or steps of the present application can be implemented by a general computing device. They can be concentrated on a single computing device or distributed on a network composed of multiple computing devices. In an embodiment, they can be implemented by program codes executable by the computing device. Thus, they can be stored in a storage device and executed by the computing device. And in some cases, the steps shown or described can be performed in a different order than here, or they can be made into individual integrated circuit modules respectively. Or multiple modules or steps therein can be made into a single integrated circuit module for implementation. In this way, the present application is not limited to any specific combination of hardware and software.

The above is only an optional implementation of the present application. It should be noted that for those skilled in the art, without departing from the principles of the present application, several improvements and modifications can be made. These improvements and modifications should also be regarded as the protection scope of the present application.

What is claimed is:

1. A narrow pulse width laser, comprising:
a pulse signal controller; and
a pulse laser emitter,
wherein an output end of the pulse signal controller is connected to an input end of the pulse laser emitter,
the pulse signal controller is configured to obtain a first pulse signal and a second pulse signal, the first pulse signal is identical to the second pulse signal, the first pulse signal is controlled to delay for obtaining a delay signal, there is a target phase difference between the delay signal and the second pulse signal, the delay signal is superimposed on the second pulse signal to obtain a target pulse signal, a pulse width of the target pulse signal is less than a pulse width of the second pulse signal, and
the pulse laser emitter is configured to emit a target pulse laser using the target pulse signal.

2. The narrow pulse width laser according to claim 1, wherein the pulse signal controller comprises:
a signal generating unit;
a delay chip; and
an AND gate chip,
wherein an input end of the delay chip is connected to an output end of the signal generating unit, an output end of the delay chip is connected to an input end of the AND gate chip, another output end of the signal generating unit is connected to another input end of the AND gate chip, and an output end of the AND gate chip is connected to the input end of the pulse laser emitter,
the signal generating unit is configured to generate the first pulse signal and the second pulse signal,
the delay chip is configured to obtain delay configuration parameters, the delay configuration parameters are configured to configure the target phase difference by controlling the delay of the first pulse signal, the first pulse signal is delayed according to the delay configuration parameters to obtain the delay signal, and
the AND gate chip is configured to perform an AND operation on the delay signal and the second pulse signal to obtain the target pulse signal.

3. The narrow pulse width laser according to claim 2, wherein the delay chip further comprises:
a delay type port configured to obtain a delay type;
a delay value port configured to obtain a delay value; and
a delay direction port configured to obtain a delay direction,
wherein the delay configuration parameters comprise: the delay type, the delay value, and the delay direction.

4. The narrow pulse width laser according to claim 3, wherein the narrow pulse width laser further comprises a parameter controller, the parameter controller is connected to the signal generating unit, the delay type port, the delay value port, and the delay direction port,
the parameter controller is configured to determine the target phase difference according to the first pulse signal, determine the delay configuration parameter according to the target phase difference, and send the delay configuration parameters to the delay chip.

5. A method for emitting narrow pulse width laser, comprising:
obtaining a first pulse signal and a second pulse signal, wherein the first pulse signal is identical to the second pulse signal;
controlling the first pulse signal to delay and obtaining a delay signal, wherein there is a target phase difference between the delay signal and the second pulse signal;
superimposing the delay signal on the second pulse signal to obtain a target pulse signal, wherein a pulse width of the target pulse signal is less than a pulse width of the second pulse signal; and
emitting the target pulse laser using the target pulse signal.

6. The method according to claim 5, wherein the controlling the first pulse signal to delay and obtaining the delay signal comprises:
obtaining delay configuration parameters, wherein the delay configuration parameters are configured to configure the target phase difference by controlling the delay of the first pulse signal; and
delaying the first pulse signal according to the delay configuration parameters to obtain the delay signal.

7. The method according to claim 6, wherein before the delaying the first pulse signal according to the delay configuration parameters, the method further comprises:
detecting a signal parameter of the first pulse signal;
determining the target phase difference according to the signal parameter; and
determining the delay configuration parameters according to the target phase difference.

8. A narrow pulse laser emission device, comprising:
an acquisition module configured to acquire a first pulse signal and a second pulse signal, wherein the first pulse signal is identical to the second pulse signal;
a control module configured to control the delay of the first pulse signal to obtain a delay signal, wherein there is a target phase difference between the delay signal and the second pulse signal;
a superposition module configured to superimpose the delay signal and the second pulse signal to obtain a target pulse signal, wherein a pulse width of the target pulse signal is less than a pulse width of the second pulse signal; and
an emission module configured to emit the target pulse laser using the target pulse signal.

9. A non-transitory computer-readable storage medium, comprising: a stored program, wherein when the program is executed, the method according to claim 5 is implemented.

10. An electronic device, comprising:
a memory; and
a processor, wherein a computer program is stored on the memory, and the processor is configured to execute the method according to claim 5 through the computer program.
